(19) United States
(12) Patent Application Publication
(10) Pub. No.: US 2014/0299184 A1
(43) Pub. Date: Oct. 9, 2014

(54) SEMICONDUCTOR DOME-ARRAY STRUCTURES USING NON-PERMANENT AND PERMANENT MOLD TEMPLATES

(71) Applicant: SOLARITY, INC., State College, PA (US)

(72) Inventors: Stephen J. Fonash, State College, PA (US); Charles Smith, University Park, PA (US)

(73) Assignee: SOLARITY, INC., State College, PA (US)

(21) Appl. No.: 14/230,257

(22) Filed: Mar. 31, 2014

Related U.S. Application Data
(60) Provisional application No. 61/806,622, filed on Mar. 29, 2013.
(60) Provisional application No. 61/826,707, filed on May 23, 2013.

(51) Int. Cl. H01L 31/0236; H01L 31/18

(52) U.S. Cl. CPC H01L 31/02366; H01L 31/18
USPC 136/256; 438/71

(57) ABSTRACT

A photo-active device is provided that has a cavity in an integrated, transparent mold material. An active material layer is disposed therein along with other layers disposed in and about said cavity to define a dome-like array architecture. A process for forming the dome-like array structure includes disposing an active layer into a series of empty periodically positioned cavities of a dome-like array template working mold material. Each of the series of empty periodically positioned cavities has curvature variations of the interior surface of the dome-array cavities optimized for device efficiency, reduction of performance sensitivity to light impingement angle, or a combination thereof. At least one of absorber layers, contact layers, spacer/transport layers, and electrode layers are also disposed in the series of cavities.

### RELATED APPLICATIONS

This application claims priority of U.S. Provisional Patent Application Ser. No. 61/806,622 filed Mar. 29, 2013; and 61/826,707 filed May 23, 2013, and which are incorporated herein by reference.

### FIELD OF THE INVENTION

The present invention in general relates to semiconductor devices, and in particular to design, fabrication, and use of devices configured as arrays of dome-like (e.g., dome-like, column-like, cone-like, and hemisphere-like) structures that are operative as photovoltaic devices (e.g., as solar cells), as light detectors (e.g., photodetectors), as light producing devices (e.g., OLEDs and LEDs), as photosynthesis devices, and as charge storage devices.

### BACKGROUND OF THE INVENTION

Historically, photovoltaic, and light detection devices such as photodetector devices, lithium drifted silicon based detectors, and photo electron effect devices have been formed as a succession of planar layers constructed to provide a functioning device. However, in the case of photovoltaic devices, for example, the high optical reflectivity of planar substrates and poor optical path length matching, have traditionally caused planar devices to exhibit less than optimum light harvesting capabilities. In recognition of the less than optimum light harvesting capabilities, such planar light-gathering devices are preferentially etched or otherwise textured to promote internal light reflection and trapping within the light harvesting portions of the device. While surface texturing incrementally improves light harvesting efficiency on such devices, the texturing process is far from uniform and inefficient in material usage. U.S. Provisional Application Ser. No. 61/559,065 filed 26 Sep. 2011, the contents of which are hereby incorporated by reference, provides a periodic arrangement of nano-elements to create an array on a device electrode inside a cell structure, as shown in FIGS. 1A and 1B, may be used to give a device configuration which can manage light reflection and trapping while aiding carrier collection in photovoltaic and detector devices [U.S. Pat. Nos. 6,399,177, 6,919,119, 7,341,774 and, 8,294,025]. The aforementioned device configuration architecture is referred to as light and carrier collection management (LCCM) devices. The LCCM configuration may also be applied to light detection, and to emission and distribution in LED-type devices.

Structures using a nano-element array to form and shape features for enhancing carrier collection and light collection management have been explored by Applicants (1-3) and, as noted above, patented by Applicants. Others have also explored similar structures (4-9), and there are a number of patent applications and patents such as those listed in (10). The common factor in all of these previous device configurations is that they are based on using an array of nano-elements inside the cell which are purposefully and actively used to define the device form and shape of subsequent material dispositions. Here the term nano-element is being used to describe a feature whose characteristic height and width are in the nano-scale or perhaps, if one adheres to the formal definition of the nano-scale, somewhat outside this scale with these characteristics in a range up to about 2000 nm.

However, the forming of these nano-element array based devices requires complex design considerations for incorporating such arrays, and in the manufacturing sequences employed to fabricate them. This is necessary to insure the positioned nano-element array will control subsequent material dispositions and thereby control the device shape and form. An alternative design and processing sequence is needed to give the flexibility of being able to avoid the necessity of using a nano-element array to control device shape and form.

### SUMMARY OF THE INVENTION

A photo-active device is provided that has a cavity in an integrated, transparent mold material. An active material layer is disposed therein along with other layers disposed in and about said cavity to define a dome-array architecture. A process for forming the dome-array structure includes disposing an active layer into a series of empty periodically positioned cavities of a dome-array template working mold material. Each of the series of empty periodically positioned cavities has curvature variations of the interior surface of the dome-array cavities optimized for device efficiency, reduction of performance sensitivity to light impingement angle, or a combination thereof. At least one of contact layers, spacer/transport layers, and electrode layers are also disposed in the series of cavities.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A is a perspective drawing showing a region of a prior art nano-element array type structure wherein the nano-elements are used to form and shape the device features. Here the nano-elements are centered in 2-D hexagonally arranged unit cells.

FIG. 1B is a cross-sectioned drawing along line A-A of FIG. 1A showing two adjacent unit cells, where the nano-elements have a variety of shapes including cones, hemispheres, and columns.

FIG. 2A is a perspective drawing showing a region of a dome-array type structure of 2-D hexagonally arranged unit cells according to embodiments of the invention.

FIG. 2B is a cross-sectioned drawing along line B-B of FIG. 2A showing two adjacent unit cells, where the features in these dome-array structures may have a variety of shapes including dome-like, hemisphere-like or cone-like, and are wider at their base (i.e., at the portion sitting on the permanent substrate) according to embodiments of the invention.

FIGS. 3A-3E are a schematic diagram of the steps of a process flow in the case of a working mold material produced by imprinting according to embodiments of the present invention.

FIGS. 4A-4D are a schematic diagram of the steps of a process flow in the case of a working mold material produced by molding according to the embodiments of the present invention.

FIG. 5A shows a cross-section similar to those of FIGS. 3B and 4A except it depicts an integrated mold material, whose light entry side (side with features 23 in this example) may be on a temporary or transparent permanent substrate (not shown). The cavity features 22 of the array of the active material side are seen. The light entry side may be flat (not shown) or contain an array of convex and concave (not shown) features or a periodic mixture.

FIG. 5B shows the section of the integrated mold depicted in FIG. 5A after the active materials and other cell layers have been disposed.

FIG. 6A is a plan-view drawing showing an exemplary unit cell arrangement. Each of the unit cells of this example is seen to locate a cavity 24 in an integrated, transparent mold material. These cavities of the exemplary unit cell have active material and other required layers disposed therein to define the dome-array architecture on the active material side.

FIG. 6B is a plan-view drawing of an example of a light entry surface of an integrated mold material showing an exemplary unit cell arrangement. These may define dome-like concave cavities or convex structures in various periodic arrangements, as needed to enhance light entry and retention. The unit cells defining the feature arrangement on one side of the integrated mold material may not necessarily align with those on the opposite side.

FIG. 6C is the plan-view drawing of another exemplary light entry surface of an integrated mold material. The unit cells may define convex or concave features in various periodic arrangements, as needed to enhance light entry and retention. The unit cells defining the feature arrangement on one side of the integrated mold material may not necessarily align with those on the opposite side.

FIG. 6D is the plan-view drawing of another exemplary light entry surface of an integrated mold material. The unit cells may define convex or concave features in various periodic arrangements, as needed to enhance light entry and retention. The unit cells defining the feature arrangement on one side of the integrated mold material may not necessarily align with those on the opposite side.

FIG. 7 is a cross-section of a transparent, integrated mold configuration showing the permanent mold material 28. In this example, the light entry side of the integrated mold material 29 is flat. The exemplary device layers and a substrate, which may be opaque, are shown in a substrate version. Alternatively the permanent mold material may serve as the substrate or reside on a transparent substrate giving a superstrate version.

FIG. 8 is a cross-sectional field emission scanning electron micrograph (FESEM) showing the deposition produced by RF sputtering of CdS and CdTe onto a working mold using the parameters of Table 1. The resulting film produced by these parameters in the inter-cavity region and in one of cavities of the cavity array in the mold is seen.

Dimensions depicted in the schematics are not necessarily to scale.

The detailed description explains the preferred embodiments of the invention.

### DETAILED DESCRIPTION OF THE INVENTION

The present invention has utility for a design and process for photo-active devices which do not utilize a nano-element array in the device to cause the formation of a repetitive, undulating structure but, instead, have a repetitive structure based on utilizing a dome-array cavity architecture. The dome-array cavity architecture has the distinct advantage of not using a nano-element array and subsequent material dispositions thereon to dictate feature form and shape. In all versions of this invention, light enters (photovoltaic and photo-detecting devices) or exits (e.g., LEDs) the active material of the dome-like features and of the inter-dome-like-feature region through the periodically undulating surface defined by the dome-array (i.e., dome-like, column-like, cone-like, hemisphere-like, etc.) features and the corresponding inter-dome-like region. In all versions of this invention, the dome-array enhances light trapping and distribution inside the device. In photovoltaic devices, for example, this may be exploited to reduce of the amount of absorber materials needed to attain or exceed the device efficiency of thicker absorber planar structures thereby giving cost savings and reducing material demands. The resulting reduction in absorber volume which can be exploited can allow photogenerated entities to be created closer to collecting surfaces thereby also contributing to enhancing performance.

Embodiments of the inventive process employ disposition of an active layer or parts thereof, possibly preceded by disposition of other layers, into the periodically patterned empty cavities of a working mold material, and subsequently forming a back contact, an electrode, and, in the case of a substrate structure, a supporting substrate all sequentially disposed onto the exposed dome-like structure material region. Following the formation of the inventive dome-array, the mold material is removed, except in the transparent, integrated mold case, and possibly a portion of the active layer and other device layers (e.g., counter contact/electrode layers) then are completed, as needed. In the case of photovoltaic devices and light detectors, embodiments of the design and process are applicable to organic and inorganic absorber materials. Embodiments of the design and process are applicable to substrate or superstrate cell configurations in one sun and concentrator uses. By way of example, photo-active devices formed according to embodiments of the present invention include solar cell photovoltaics, photosynthesis devices, light detection devices, and light producing devices.

Transparent, integrated mold variants of the inventive process employ disposition of an active layer preceded by disposition of other device layers (e.g., contact/electrode materials) into the periodically patterned empty cavities of a working integrated, transparent mold material. Subsequent formation of a back contact, an electrode, and a supporting substrate (in the substrate version) all sequentially disposed onto exposed dome-like (dome-like, cone-like, column-like, and hemisphere-like) material and inter-dome region then occur. Following this formation of the inventive dome-array, the transparent mold material is not removed in these embodiments but remains in place. It therefore becomes a part of the completed device and may function to protect the device. Further, the side of this integrated mold material facing the incoming light may also be patterned to further enhance light coupling and trapping. When the side of this integrated mold material facing the incoming light is exposed to the environment directly, its pattern may also be used to keep this surface clean. The cleaning function results from the well-known Lotus Effect (6). This embodiment is also applicable to organic and inorganic absorber materials and may be finished as a substrate or superstrate configuration. In either case, light enters through the light entry surface of the transparent, integrated mold and enters the active material volume through the periodically undulating surface defined by the dome-array (dome-like, column-like, cone-like, and hemisphere-like) features and the corresponding inter-dome-like region; i.e., light enters through the dome-array.

The basic architectures and process flow described in the present invention can be applied to photovoltaic devices, photosynthesis devices, light detection devices, and light producing devices. Embodiments of the inventive design and fabrication approach permit low cost, manufacturable devices. The inventive embodiments disclosed herein all have the following advantages: (1) the embodiments do not need a dry-etching step for cleaning the exposed inter-dome portion after dome material disposition into the cavities of the mold, (2) with the proper mold material selection, the inventive embodiments may use high processing temperatures during the process steps; (3) embodiments do not use an etching step to define the dome-array, and (4) embodiments do not need an etching step for removing any base portion of the dome-array material. The approaches disclosed herein for design and manufacturing not only simplify the processing compared to approaches requiring a positioned array of nano-elements for device shape and form control, but they also offer freedom in selecting process conditions for subsequent steps. These potential advantages combined with the capabilities of high throughput with low cost production offered by roll-to-roll processing critically contribute to low cost manufacturing by embodiments of the present invention, and offer market competitiveness advantages.

In addition, the approach disclosed herein can, as noted, use a transparent, integrated mold material thereby giving the further advantages of (1) forming and utilizing the dome-array architecture without requiring a mold material removal step, (2) offering the ability to pattern the incoming light side of the integrated mold material to further enhance light coupling, and (3) offering the options of using the integrated mold material as a cleaning layer and/or a protection layer for the device beneath. Use of the transparent, integrated mold material approach also means devices may be finished as substrate or superstrate configurations. Further, the integrated mold material approach does not need any anti-adhesion layer utilization, often important to separation processing, between the mold and the undulating dome-like (dome-like, cone-like, column-like, or hemisphere-like) structure surface. Anti-adhesion layers may be required in the non-integrated mold material approaches.

The dome-array design and fabrication control approach used in embodiments for creating effective structures for photo-active devices will be specifically discussed in the context of solar cells. However, embodiments of the present invention have application to various photo-active devices producing or utilizing light, the latter including solar cell photovoltaics, photosynthesis devices, and light detection devices. In the exemplary embodiments discussed, the working mold material arrayed, with empty cavities used for forming the device arrays, is prepared by creating a master template. If this master template is used to produce imprinting (including embossing) templates, the master template is formed using standard techniques such as lithography and etching to have what is termed the positive of the desired array pattern. The master template is used to produce the imprinting template which then is a negative. The imprint template (e.g., a roller, diaphragm, or plate tool) is forced, using conventional imprint techniques, into contact with a mold material creating the working mold material with the positive array pattern, which is the desired pattern into which material is disposed in creating the device. Alternatively, if this master template is used to produce patterned mold material directly without imprinting, it has what is termed the negative of the desired array pattern. The master template is then used to produce the working mold material, which is positive, by first positioning a liquid or vapor precursor of the working mold material into the master template. This step is followed by a curing of this precursor employing various chemical, physical, or both treatments including heating and radiation exposure (e.g., ultra violet (UV)). The resulting array of cavities in the mold material is the pattern into which material is disposed in creating the device in this molding approach.

It is noted that in either the imprinting or molding approach, the master template can be used multiple times to create multiple positive mold material arrays. In the case of molding, this merely requires reuse of the master template. In the case of imprinting, the imprinting tool can be used multiple times and, when needed, can be replaced by a new tool using a sequence of positive/negative pattern formation. Mold materials for these purposes can vary and can include a variety of materials from polymers to spin-on-glass types and to sol-gel (e.g., ZnO sol-gel, TiO2 sol-gel) materials.

The curvature variations of the interior surface of dome-array cavities may be determined by adjusting feature shaping in the master mold. The resulting dome-like, hemisphere-like, cone-like, column-like, etc. cavity curvature variations across the cavity interior surface can be optimized for (1) device efficiency and/or (2) reduction of performance sensitivity to light impingement angle. The disposing of material into the cavities of a working mold material for forming a dome-array structure includes disposing material into the cavities and onto the inter-cavity region. The materials involved include active layer materials, or their precursors and may include optical spacer/transport controlling (e.g., hole transport/electron blocking and electron transport/hole blocking) layers, contact layers, and electrode layers. It may also require other device layers. These mold cavities are generally wider at their opening than at their bottom (i.e., they have what may be termed a dome-like, hemisphere-like, cone-like, or similarly shaped features collectively referred to as dome-like herein) for facilitating disposing material into the cavities and subsequent separation, when undertaken. The working mold material is chosen to be compatible with the processing and processing temperatures to which the mold material will be exposed. Active layer materials disposed into these cavities may comprise at least one of semiconductor quantum dots, nc-Si, CIGS, CdTe, iron pyrite, dyes or other inorganic or organic absorber materials. The one or more active layers which are disposed into the empty cavity array of the working mold material consists of at least one absorber, and one or more of the layers may be doped. The active layer(s) may comprise the materials, or some of the materials, necessary to have p-i-n, p-n, surface barrier (e.g., Schottky barrier type structures), heterojunction (including bulk heterojunction), and dye sensitized collection structures. The working mold material itself is formed by imprinting or molding using a master pattern, as noted. The disposing of material into cavities as well as onto inter-cavity regions of the mold template may be accomplished by using one or more of a variety of physical and chemical deposition techniques such as physical or chemical vapor deposition (including close spaced sublimation (CSS) deposition), in situ growth, and atomic layer deposition, as well as, by employing stamping and impressing techniques (e.g., impressing quantum dots into the cavities).

The one or more active layer materials disposed into the cavities, by whatever means, essentially fill or partially fill these cavities, which are arranged in a repetitive lattice pattern (e.g., hexagonal, triangular, or square unit cells). The one or more active layer materials and other possible device layers also cover the working mold material surfaces between the cavities of the array. A device electrical contact is disposed onto the entire region of exposed material. Subsequently, the electrical contact material may be further built-up in thickness, or another material may be disposed. In either case an electrode is finally formed. This interconnected contact base provides an electrode, as well as mechanical and electrical continuity. The contact base may function as the substrate or may be attached to a substrate so that, in either case, a mechanically stable platform is created. All material dispositioning processes, contact base processing, and the processing needed to complete the device, may be batch processing but are amenable to being done in continuous processing fashion (e.g., roll-to roll).

The dome-array (i.e., arrayed dome-like, hemisphere-like, cone-like, or similarly shaped features) resulting from embodiments of the inventive design and process flow has at this point a supporting mechanical substrate, but is otherwise covered with the mold material. This mold material is then removed by means of chemical phenomena (e.g., etching or dissolution), physical phenomena (e.g., mechanical separation), or both. This removal may also involve external energy sources such as heat, ultra violet (UV) radiation, etc. If the mold material has been selected to function as an integrated, transparent mold material, then it is not removed and remains as an integral part of the device and may have functions such as device protection, enhancing light entry and trapping, and/or enhancing surface cleaning.

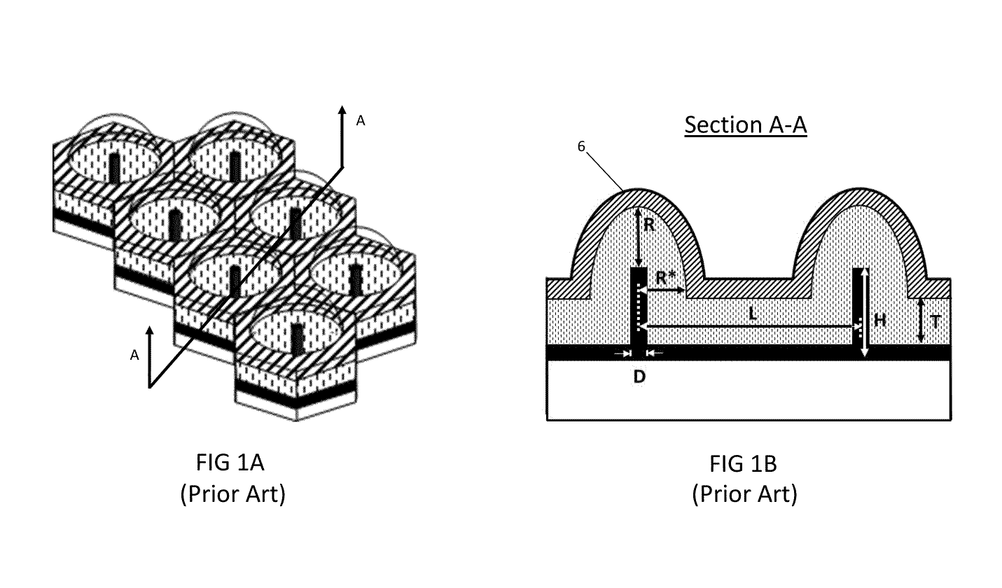

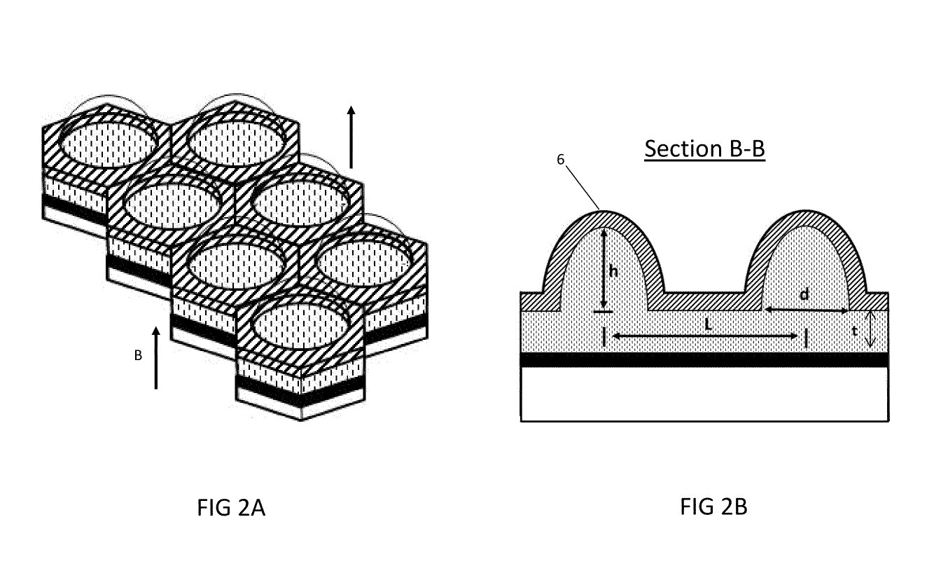

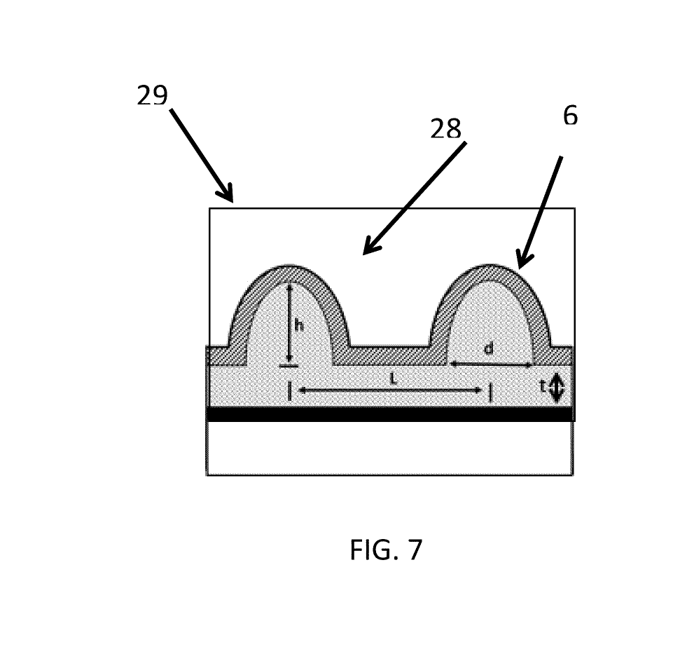

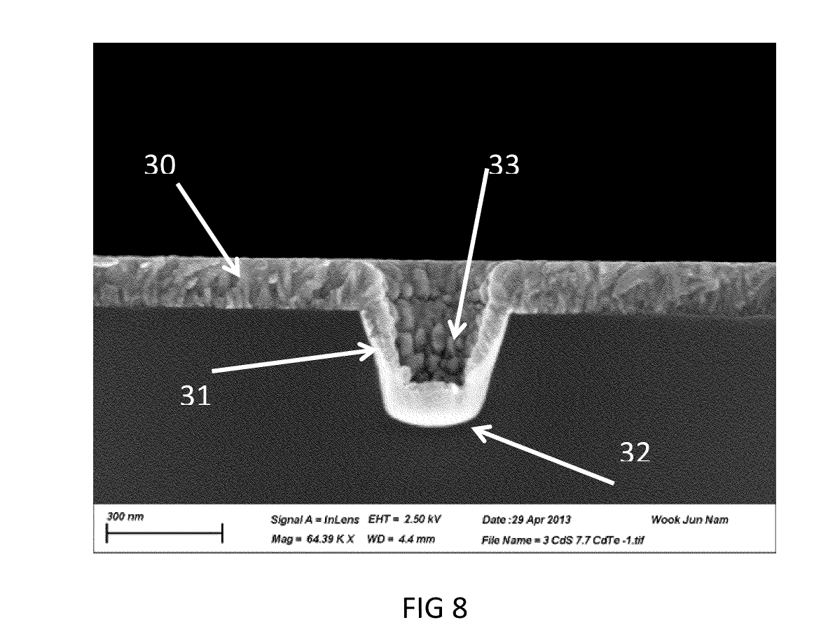

With the removal of mold material in the non-permanent mold designs, there may be a cleaning step included. At this point, the now exposed dome-like structures of the dome-array may have disposed on them the final layers necessary to complete the cell fabrication. These final layers may include a dopant layer, a spacer layer for aiding in controlling light distribution and in forming selective Ohmic contacts, a light absorber layer, a conductor, or a top (i.e., counter) electrode layer. The result is the dome-array device such as that shown in FIGS. 2A and 2B. The dome-like architecture is distinctly different from that of FIG. 1. In all cases of the dome-like designs and processing designs of this invention there is no utilization of a nano-element array to dictate solar cell shape and form. If a nano-element array is present in the final device, it played no role in creating the dome-like architecture. Photovoltaic structures using the architecture and processing results exemplified by FIGS. 2A and 2B, as well as those with the integrated mold material of FIG. 7 and/or with the non-shape, non-form controlling nano-element array possible with the structure of FIG. 8, may function as solar cells used as one sun devices or they may be combined with luminescent solar concentrator films or with micro-optics elements positioned in concert with the array for concentrator devices. The architecture and processing exemplified by FIGS. 2A and 2B and FIG. 7 as well as that possible with FIG. 8 may be used in other light responsive devices and in light producing devices. Depending on the transparency properties of the materials on the light exit/entry side, including the contacts, electrodes and substrate materials, the devices of FIGS. 2A and 2B and FIG. 7 as well as those possible with FIG. 8 may be utilized in substrate or superstrate configurations. As previously noted, the processing flow may be a continuous one and therefore may be done in a roll-to-roll manner.

### EXAMPLES

### Example 1

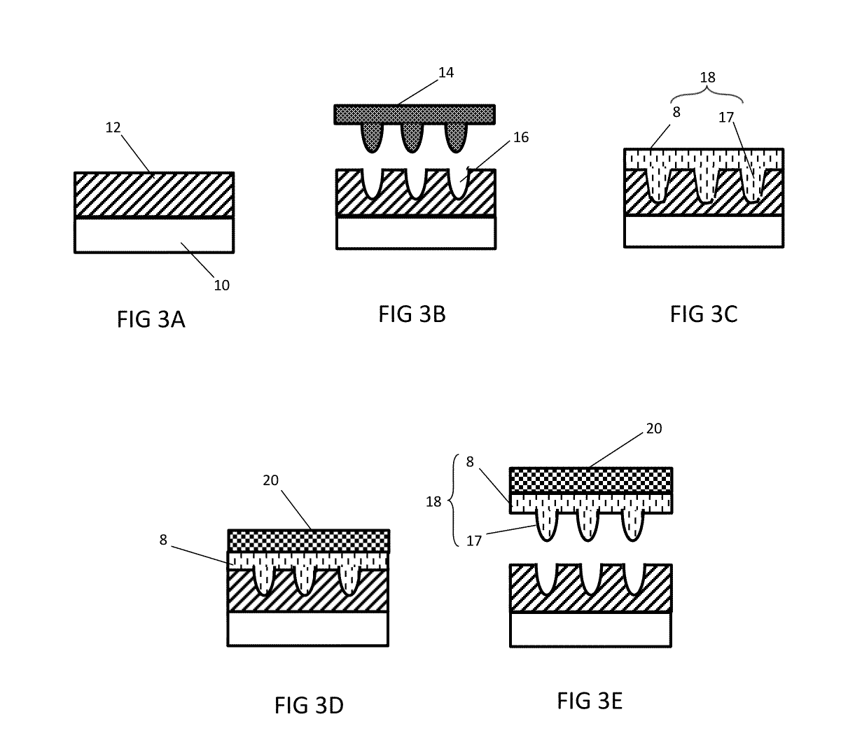

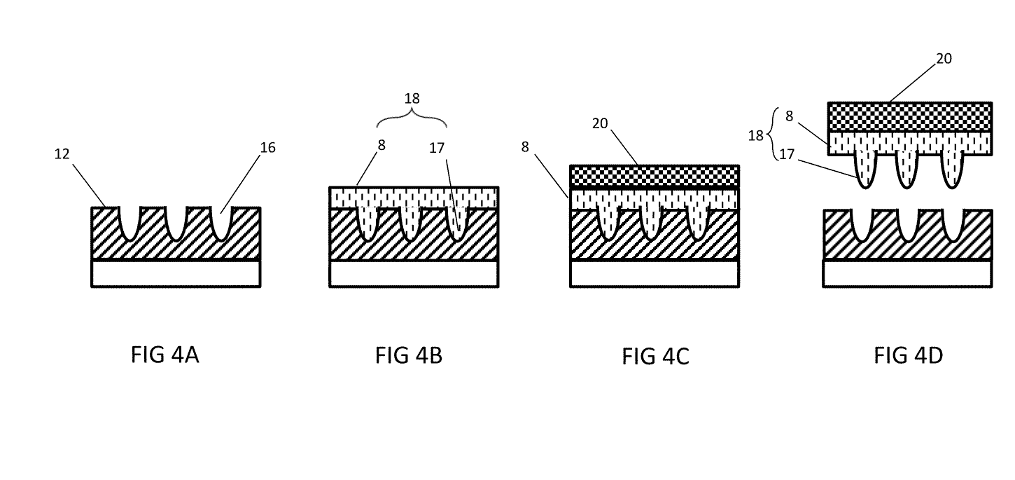

Additive processes such as physical positioning, physical vapor deposition, chemical vapor deposition or some combination are used to dispose all of the active layer components including at least one of absorber material and of other layers for doping, spacer/transport control, and the top contact layer/electrode into the/empty cavity and the regions between cavities on the mold material, before back contact/back electrode/substrate formation. The result is 17 of FIG. 3C or 4B. The top (not purposefully undulating) surface of 17 may not be flat (planar), depending on the disposition techniques. With 17 in place, back contact formation, and back electrode deposition are carried out. The latter may be a continuation of the contact former deposition. If the result needs to be flat (e.g., for substrate 20 attachment or deposition) or if 17 needs to be flat and/or reduced in thickness in the inter-dome-like feature regions for better device operation balance, this can be accomplished by standard planarization techniques, including the use of chemo-mechanical polishing (CMP) and/or etching, applied to one or more of the layers of 17. Substrate deposition or attachment follows after electrode formation. After this processing the mold material is removed in this non-permanent mold example of this invention. The resulting device is shown schematically in FIG. 2.

If imprinting is employed in the array formation, the process flow starts with a mold material 12 on a working substrate 10 as seen in FIG. 3A. The empty cavities 16 in the mold material 12 are then created as seen in FIG. 3B by imprinting with pattern material 14. In addition to the physical contacting of imprinting, heat or radiation (e.g., UV exposure) may be provided to aid in the pattern transfer into the mold material 12. As is well known in imprinting technology, films may be positioned onto the material surface prior to contact, to aide in the subsequent removal of pattern material 14 from the mold material. If imprinting is not utilized, the required morphology of the mold material may also be formed by positioning a liquid-like mold material such as polyurethaneacrylate (PUA) or a vapor-like mold material precursor into a master mold which has the negative of the required pattern. After curing the required positive pattern, attached to a working substrate, is seen in the mold material 12 as shown in FIG. 4A.

Whether formed by imprinting or molding, the cavities 16 in the mold material 12 of FIG. 3B or 4A may be of various dome-like, hemisphere-like, cone-like, or similar shapes with a maximum dimension d at their base, a maximum depth h, and array spacing L as shown in FIG. 2B. The ratio h/d defines the cavity aspect ratio. The parameters d, h, and L are selected such that the final thickness height h and final width d along with thickness t and array spacing L seen in FIG. 2B after device fabrication and back contact formation maximize device performance. In the case of photovoltaic devices (e.g., solar cells), the parameters d, h, and L are selected to maximize photo conversion efficiency (PCE) performance and/or reduce cost per Watt performance. As shown, L is established by the cavity pattern whereas d and h depend on the features of the working mold material as well as on the properties and thicknesses of the layers used in depositing the one or more absorbers, and any other layers used for doping and optical spacer and/or transport control. The thickness t in FIG. 2B depends on the processing parameters of the one or more materials positioning processes involved with the active layer and other layers used for the doping and optical spacer and/or transport control optimization needed to enhance performance. The top contact/top electrode 6 in FIG. 2B is disposed into the dome, hemisphere, or cone-like (collectively referred to as dome-like) cavities and inter-cavity regions shown in FIGS. 3B and 4A in this example 1. The range of d and h is expected to be approximately 50 to 2000 nm, depending on the organic or inorganic absorber or absorbers used, the active layer transport properties (e.g., photogenerated entity lifetimes and diffusivities), and on the device collection structure utilized (e.g., p-n, p-i-n, heterojunction, bulk heterojunction, or surface barrier). The final structure 18 resulting from all materials deposition from top electrode 6 to the back electrode 8 is shown in FIG. 3C or 4B. The deposition or attachment of the substrate 20 is shown in FIG. 3D or 4C. Device array removal from the working mold material is shown in FIGS. 3E and 4D, and may be done by physical means, chemical means, or some combination thereof. The parameter L establishing the array spacing is approximately 50 to 2500 nm, and may be arranged to yield a variety of array patterns (e.g. square, hexagonal, triangular). The resulting structure shown in the example of FIG. 2A is a substrate cell with a transparent top electrode and a back electrode of a high conductivity material (e.g., a metal) on a substrate. The absorber materials used may include, but are not limited to CdTe, nc-Si, organics, dyes, and quantum dots. In the case of quantum dots, the dot positioning may include their being imprinted (e.g., impressed) into the cavities. The sequencing shown in FIG. 3 or FIG. 4 is intended to convey that manufacturing can be accomplished using roll-to-roll processing.

### Example 2

The absorber copper indium gallium selenide (CIGS) is disposed to form a heterojunction solar cell device. However, the design and sequencing are not limited to that material system, nor to its specific deposition methods. The present example has two variants. In one variant, the CIGS material is deposited (e.g., by co-evaporation) into the empty cavities and onto the regions between these cavities of the working mold material, and a back contact is formed. This back contact may not be flat (planar), depending on the disposition techniques and parameters. If planarization is needed for 17 and/or 18, it may be attained using the approaches discussed in Example 1. After back contact formation, that material or another disposed material may serve as the back electrode, as needed, and a substrate is attached (e.g., bonded) or deposited (e.g., vacuum deposition, laser ablation, or electroplating). The resulting dome-like, hemisphere-like, cone-like, or similarly shaped features, with CIGS and these other materials, are then separated from the mold material. A cadmium sulfide (CdS) layer is then formed (e.g., by chemical-bath-deposition (11)) on the free surface of these arrayed CIGS dome-like, hemisphere-like, or cone-like features and the exposed CIGS planar surfaces between these. This step may require a CIGS surface cleaning/conditioning prior to CdS layer formation. Subsequently, a sputtered resistive/conductive zinc oxide (ZnO) bi-layer may be deposited (11). It may be advantageous to replace the ZnO/CdS system with another (e.g., Zn1−xMgxO (12)). In any case, the resulting device is shown schematically in FIGS. 2A and 2B. The top (undulating) electrode formation may require the addition of an additional transparent metal oxide layer.

In the other variant, CIGS material is deposited into the empty cavities, and onto the regions between these cavities of the mold material, after positioning into the cavities of one or both of the top layers (e.g., either one or both of ZnO/CdS or Zn1-xMgxO, etc.). The top (undulating) electrode material may be deposited similarly or after mold removal. The back contact is then formed and the mold material is removed and processing concluded, as needed, producing the device shown schematically in FIGS. 2A and 2B.

In the current example, the process flow may again start with the working mold material 12 on a working substrate 10 as shown in FIG. 3A. The empty cavities 16 in the mold material are then created as shown in FIG. 3B by imprinting. In addition to the physical contacting of imprinting, heat or radiation (e.g., UV exposure) may be provided to aid in the pattern transfer into the mold material 12. As is well known in imprinting technology, films may be positioned onto the mold material surface prior to contact to aide in the removal of pattern material 14 from the mold material. Alternatively, the imprint approach may not be used but the morphology of the working mold material may also be formed by positioning a liquid-like mold material such as PUA or a vapor-like mold material precursor into a master mold which has the negative of the pattern seen in the mold material in FIG. 4A. After curing of the working mold material and positioning it on the working substrate, the mold material is a solid with the appearance as shown in FIG. 4A.

Whether formed by imprinting or molding, the cavities 16 in the mold material may be of various dome-like, hemisphere-like, cone-like or similarly shaped features with a maximum dimension d at their base, a maximum depth h, and array spacing L. These parameters d, h, and L are selected such that the final thickness height h and final width d along with thickness t and array spacing L seen in FIG. 2B after device fabrication and back contact formation maximize device performance. In the case of photovoltaic devices (e.g., solar cells), they are selected to maximize photo conversion efficiency (PCE) and/or cost/Watt. As shown, L is established by the pattern transfer material whereas the d and h chosen depend on the structure of the pattern transfer material as well as the layer thickness used in depositing the CIGS absorber and subsequently positioned materials. In this example embodiment, both variant 1 and 2 give the situation shown in FIG. 3C or 4B, as appropriate. The thickness t of FIG. 2 depends the CIGS thickness, as well as that of the other component materials. The top contact/electrode 6 in FIG. 2B is deposited onto the CdS of the array features after mold material removal in the first variant, whereas it may or may not be present in the features prior to mold material removal in the second variant. The range of d and h is approximately 50 to 2000 nm. The structure 18 shown in FIGS. 3C and 4B is the final device configuration, if all layers are to be deposited prior to mold material removal. The deposition or attachment of the substrate 20 is accomplished in FIGS. 3D and 4C and removal from the mold material is shown in FIGS. 3E and 4D. In variant 1, the ZnO/CdS or Zn1−xMgxO or alternative dispositions are done after the separation shown in FIG. 3E or 4D. In variant 2, final depositions are done as needed after the separation. Separation may be done by physical means, chemical, means, or some combination thereof. The parameter L establishing the array spacing is expected to be approximately 50 to 2500 nm, and may be arranged to yield a variety of array patterns (e.g., square, hexagonal, triangular). The resulting structure shown in FIG. 2 is a substrate cell with a transparent top electrode (e.g., a transparent metal oxide), and a back electrode of a high conductivity material (e.g., a metal) on a substrate.

The sequencing in FIG. 3 and FIG. 4 is meant to convey that the processing may be accomplished using roll-to-roll processing.

### Example 3

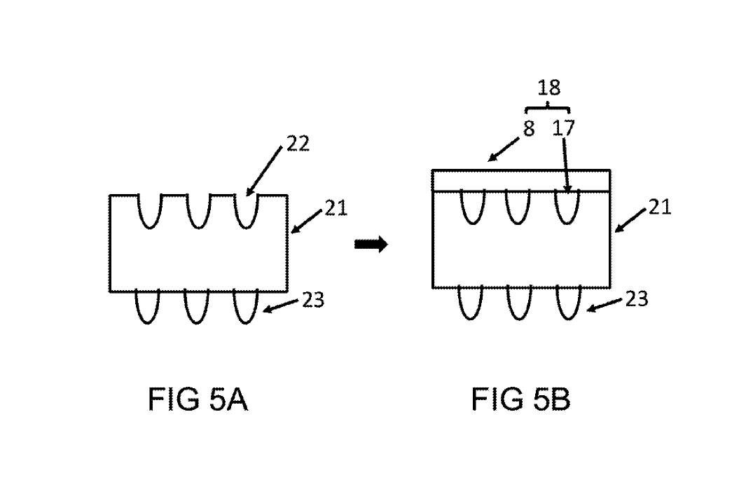

In this example, the mold material key to forming these dome-array architectures, which are all distinguished by having mold cavities control solar cell features, is transparent and integral to the final device; i.e., it is permanent and not removed. The mold materials in this case may include glass-like materials, polymers, transparent conductive oxides, or any material amenable to the process flow and transparent to light across the spectrum of interest. The material may be chosen from among insulators, semiconductors, or conductors. It may or may not be or be a part of the contiguous electrode. Physical positioning, physical vapor deposition, chemical vapor deposition (includes CSS here and elsewhere) or some combination is used to dispose device layer components including the top contact layer/electrode (on side of incoming light) and at least one absorber material and other layers as needed for doping as well as spacer/transport control into the empty cavity and the regions between cavities on the mold material, before back contact/back electrode/substrate formation. The result is 17 of the schematic of FIG. 5B. This is then followed by back contact formation/back electrode 8 disposition which may be a continuation of the contact former deposition. This all results in 18 of that figure. Substrate deposition or attachment, after electrode formation, is then utilized (not shown).

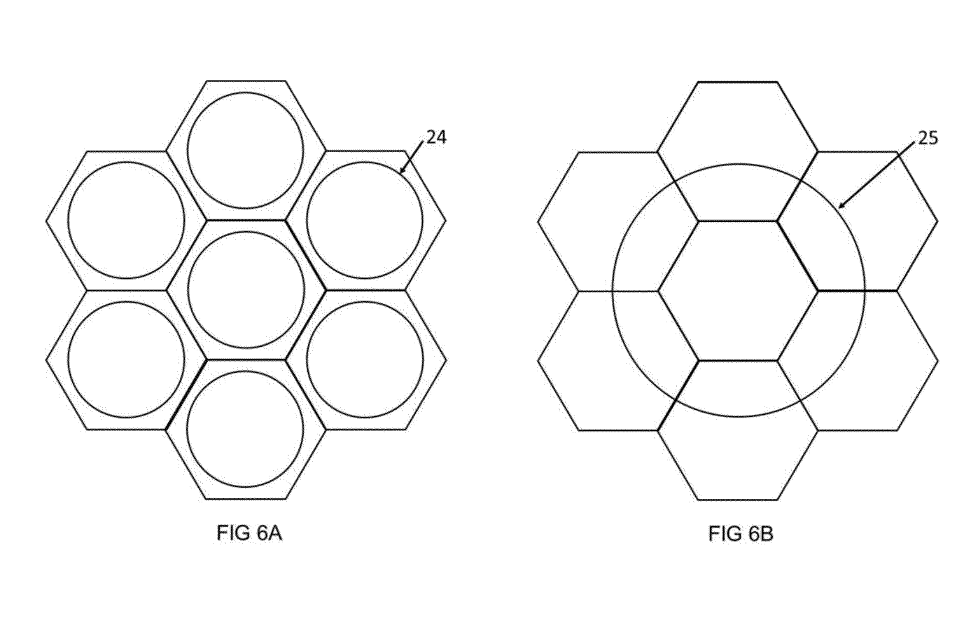

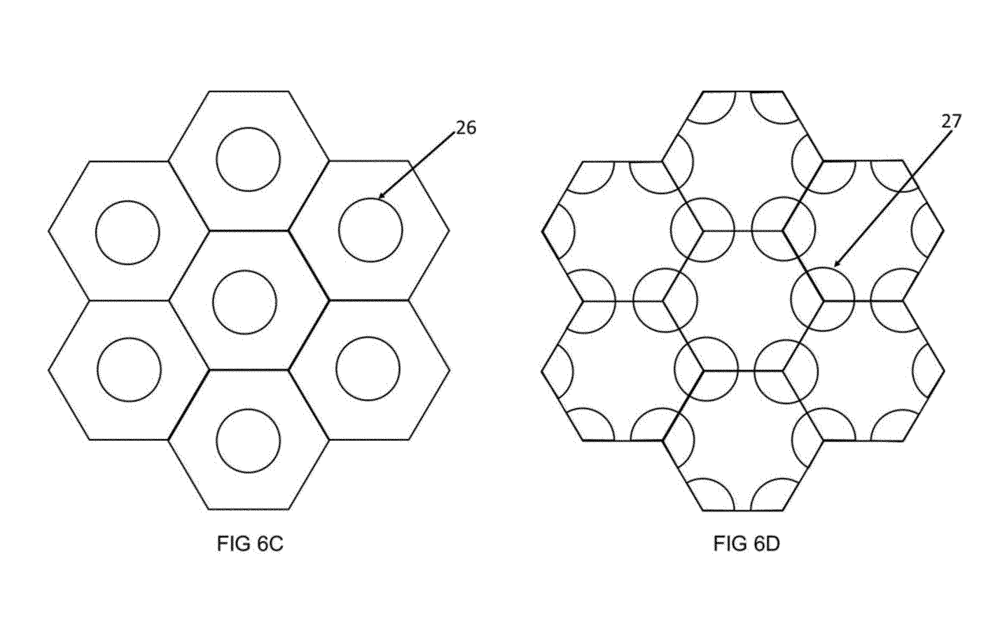

The cavities 22 in FIG. 5A in the integral, transparent mold material of this embodiment are arranged in an array pattern, such as that shown in FIG. 6A, in the integral mold material. This figure gives a plan-view drawing showing an exemplary unit cell arrangement composed of hexagonal cells. Each of these cells of this example is seen to locate a cavity of the pattern 24 which may have a variety of shapes including dome-like, hemisphere-like or cone-like. The surface of the integrated mold material opposite to that containing the cavities 22 with the pattern 24 of the example in FIG. 6A interfaces with the incoming light. It may be a flat surface or may contain cavity-like (concave) features (e.g., 25, 26, 27 in FIG. 6), dome-like (convex) features (e.g., 25, 26, 27 in FIG. 6) or both in various periodic arrangements (e.g., the exemplary hexagonal arrangements of FIG. 6B-6D), as needed to enhance light entry and retention. The unit cells of the cavity side may not have the same spacing L nor alignment as those of the light entry side L′. The unit cells of the light entry side define the periodic positions of dome-like convex structures, cavity-like concave structures, or both. These periodic features may have a variety of concave and convex shapes including dome-like, hemisphere-like or cone-like. The structure of the integrated mold material surfaces may be established by imprinting (stamping plates or rollers) or molding, as discussed in detail for the other examples. As used in this disclosure, imprinting includes embossing. The periodic patterns of the cavity side and of the light entry side may (e.g., by using opposing plates or rollers) or may not be imprinted or molded in the same step.

FIG. 5A shows a cross-section of the integrated mold material 21 after its formation. The dome-like, as yet unfilled, concave features 22 of the cavity side of the integrated mold material are seen. The light entry side, shown in this example to have only convex features 23, may be positioned on a temporary substrate (not shown). The light entry side may be flat (not shown) or contain dome-like shapes, as seen here. Unlike the features of U.S. Pat. No. 7,851,694, the features of the light entry side of 21 are necessarily periodic and less than about 2 microns in size. Most importantly, unlike the features of U.S. Pat. No. 7,851,694, material 21 is an integrated mold material used also to define the unique device dome-array with the transparent, integrated mold 28 seen in FIG. 7 (here 28 is seen with a flat light entry surface).

Whether formed by the imprinting or molding approaches discussed in examples 1 and 2, the cavities 22 used to define this dome-array in the mold material 21 may be of various dome-like, hemisphere-like, cone-like, or similar shapes with a maximum dimension d at their base, a maximum depth h, and array spacing L and collectively termed dome-like herein. The parameters d, h, and L are selected such that the final thickness height h and final width d along with thickness t and array spacing L after device fabrication and back contact formation maximize device performance. FIG. 5B shows the section of the integrated mold depicted in FIG. 5A after the active materials and other cell layers have been disposed. The permanent substrate (not shown) is subsequently positioned onto 8 of 18 in the substrate configuration by approaches such as deposition, growth, or attachment. In the case of photovoltaic devices (e.g., solar cells), the parameters d, h, and L are selected to maximize photo conversion efficiency (PCE) and reduce cost per Watt. As shown, L is established by the pattern whereas d and h depend on the features of the working mold material as well as on the properties and thicknesses of the layers used in disposing the one or more absorbers, and any other layers used for doping and optical spacer and/or transport control. The thickness t depends the extent of the one or more depositions as well as well as that of any other back layers used for the doping and optical spacer and/or transport control optimization needed to enhance performance. The top contact layer 6 in FIG. 7 is first deposited into the dome, hemisphere, or cone-like cavities 22 of FIG. 5B. The range of d and h is expected to be approximately 50 to 2000 nm, depending on the organic or inorganic absorber or absorbers used, the active layer transport properties (e.g., photogenerated entity lifetimes and diffusivities), and on the device collection structure utilized (e.g., p-n, p-i-n, heterojunction, bulk heterojunction, or surface barrier). The parameter L establishing the array spacing of the cavities containing device materials is approximately 50 to about 2500 nm, and may be arranged to yield a variety of array patterns (e.g., square, hexagonal, triangular). The absorber materials used in these cavities may include, but are not limited to CdTe, CIGS, nc-Si, a-Si:H, quantum dot materials, other inorganics and organics including dyes. In the case of quantum dots, the dot positioning may include their being imprinted (impressed) into the cavities. The parameter L establishing the array spacing of cavities containing device materials is approximately 50 to 2500 nm, and may be arranged to yield a variety of array patterns (e.g., square, hexagonal, triangular). The parameter L′ defines the unit cells of the light entry side with their dome-like convex structures, cavity-like concave structures, or both. This L′ and the array geometry type chosen are determined so as to ensure that the arrays on both sides of the integrated, transparent mold material aid in device performance.

### Example 4

This example exploits the situation in which the cavity-inter-cavity region does not have a flat active layer, exposed surface after active layer dispositioning. This example specifically utilizes one or more of d, h, aspect ratio h/d, material type, and disposition type and parameters to adjust the thicknesses of the material layers disposed on the inter-cavity region 30, on the side walls of a cavity 31, and on the bottom of a cavity 32 in FIG. 8 to control the void region 33 of FIG. 8.

In this specific example, a CdS/CdTe heterojunction solar cell is disposed by first RF sputtering CdS into the empty working mold cavities and, of course, onto the adjacent, inter-cavity regions. This is followed by RF sputtering of CdTe into the working mold cavities and onto the adjacent, inter-cavity regions. The result, after the deposition of these two films using the parameters of Table 1, is seen in the field emission scanning electron micrograph (FESEM) cross-section given in FIG. 8. As may be noted, after the RF sputter deposition of Table 1, the CdS/CdTe active layer has deposited into the working mold cavity but has not yielded a flat surface for any spacer/transport control layer or contact layer/electrode layer(s) deposition. With the presence of the resulting void seen in FIG. 8, these subsequent depositions can fill at least a portion of this void and thereby produce a nano-element in each dome-like feature. In the case of these CdS/CdTe cells, the back contact/electrode layer used was Au/Cu which can fill the void seen in FIG. 8 and produce such a nano-element in each dome-like feature. The result, after full processing, is a device which looks similar to that of FIG. 1. However, in the devices of FIG. 1, the nano-elements formed and shaped the dome-like features. In this example, the dome-like cavities 16 in FIGS. 3B and 4A and the materials disposed into these cavities and inter-cavity regions create the voids which form and shape the nano-elements. While a metal was used in this example, the resulting nano-element array can be comprised of metals, conducting metal oxides and other conducting or semiconducting materials. Insulators can be used if covered with a conducting or semi-conducting film or if the nano-elements are not intended to assist in photogenerated entity (electrons, holes, excitons) collection. The working mold seen in the bottom of FIG. 8 is not transparent and must be removed. However, a permanent transparent, integrated working substrate may be employed, if desired.

TABLE 1
CdS/CdTe film deposition conditions

| | Process | Process | Ar Gas Flow | RF | Deposition |
|---|---|---|---|---|---|
| Material | Temperature | Pressure | Rate | Power | Rate |
| CdS | 270 C. | 18 mTorr | 32 sccm | 35 W | 21 nm/min |
| CdTe | 270 C. | 18 mTorr | 32 sccm | 20 W | 18 nm/min |

If it is necessary to adjust the active material thickness in the inter-cavity region, the thickness t of the layers in this region may be tailored using the well-known techniques employed in planarization such as CMP and/or etching. This may be done before or after nano-element disposition.

If the device and the processing are designed to give a non-flat active layer surface resulting in voids in cavity regions as demonstrated in FIG. 8, the structure, as discussed above, can be exploited to give a nano-element array with an element in each dome-like feature. This array is formed after the formation of the dome-like array and does not control is positioning, shape, or form. This nano-element array does penetrate the active layer and can affect light trapping and collection as well as provide more effective collection of photo-generated entities from the active material volume. If used with a transparent, integrated working substrate (e.g., 10 in FIG. 3), the approach of this example can give a light and carrier collection-enhancing solar cell structure (1) without using a nano-element array to create and control the sought-after dome-like features, (2) yet having a nano-element array to enhance collection, (3) and without the requirement of a separation step anywhere in the solar cell processing. Indeed, in both Example 3 and 4, the mold and the substrate 10, if transparent, can be permanent parts of the device.

### REFERENCES CITED

1. Nam W J, Fonash S J, Liu T, and Wagner S, “A Study of lateral collection single junction a-Si:H solar cell devices using nano-scale columnar array structures”, the 35^{th} Photovoltaic Specialists Conference, Honolulu, Hi. (2010).
2. Nam W J, Ji L, Benanti T L, Varadan V V, Wagner S, Wang Q, Nemeth W, Neidich D, and Fonash S J, “Incorporation of a light and carrier collection management nano-element array in superstrate a-Si:H solar cells”, Appl. Phys. Lett. 99, 073113 (2011).
3. Wook Jun Nam, Liming Ji, Vasundara V. Varadan, and Stephen J. Fonash, “Exploration of nano-element array architectures for substrate solar cells using an a-Si:H absorber”, J. Appl. Phys. 111, 123103 (2012).
4. Zhou D and Biswas R, “Photonic crystal enhanced light-trapping in this film solar cells”, J. Appl. Phys. 103, 093102 (2008).
5. Ferry V E, Verschuuren M A, Li H B T, Verhagen E, Walters R J, Schropp R E I, Atwater H A, and Polman A, “Light trapping in ultrathin plasmonic solar cells”, Optics express 18, A237 (2010).
6. Zhu J, Hsu C M, Yu Z, Fan S, and Cui Y, “Nanodome solar cells with efficient light management and self-cleaning”, Nano Lett. 10, 1979 (2010).
7. Biswas R and Xu C, “Nano-crystalline silicon solar cell architechute with absorption at the classical 4n² limit”, Optics Express 19, A664 (2011).
8. Vanecek M, Babchenko, Purkrt A, Holovsky J, Neykova N, Poruba A, Remes Z, Meier J, and Kroll U, “Nanostructured three-dimensional thin film solar cells with very high efficiency potential”, Appl Phys Lett. 98, 163503 (2011).
9. Deceglie, M., Ferry, V., Alivisatos, A. P., and Atwater, H., “Design of nanostructured Solar Cells Using Coupled Optical and Electrical Modeling”, Nano Lett., X, yy, (2012).
10. U.S. Pat. No. 6,852,920, U.S. Pat. No. 6,946,597, U.S. Pat. No. 7,253,117, U.S. Pat. No. 7,291,782, U.S. Pat. No. 7,462,774, U.S. Pat. No. 7,511,217, U.S. Pat. No. 7,605,327, U.S. Pat. No. 8,093,489, U.S. Application 2011/0030770, U.S. Application 2011/0180127, U.S. Application 2011/0048518, U.S. Application 2011/0277827, U.S. Application 2010/0090341
11. Repins, R., Contreas, M., Egaas, B., DeHart, C., Scharf, J., Perkins, C., To, B., and Noufi, R., “A 19.9%-efficient ZnO/CdS/CuInGa Se2 Solar cell with 81.2% Fill Factor”, progress in photovoltaics: Research and Applications, 16, 235, (2008).
12. Minemoto, T., Harada, S., and Takakura, H., “Cu(In, Ga) Se2 superstrate-type solar cells with Zn1-xMgxO buffer layers, Current Applied Physics, 12, 171, (2012).
13. U.S. Pat. No. 7,851,694 B2

Any patents or publications mentioned in this specification are indicative of the levels of those skilled in the art to which the invention pertains. These patents and publications are herein incorporated by reference to the same extent as if each individual publication was specifically and individually indicated to be incorporated by reference.

The foregoing description is illustrative of particular embodiments of the invention, but is not meant to be a limitation upon the practice thereof. The following claims, including all equivalents thereof, are intended to define the scope of the invention.

1. A photo-active device comprising:
a cavity in a mold material;
at least an active material layer; and
another layer disposed in and about said cavity to define a dome-like array architecture for the photo-active device.

2. The device of claim 1 further comprising a plurality of cavities similar to said cavity, said plurality of cavities having a periodic spacing.

3. The device of claim 2 wherein the periodic spacing is determined by a unit cell.

4. The device of claim 3 wherein said unit cell is hexagonal.

5. The device of claim 1 wherein said mold material is integrated, transparent, and electrically conductive.

6. The device of claim 1 wherein said active material comprises one or more layers formed of at least one of CdTe, CIGS, nc-Si, dyes, or quantum dots positioned within said cavity.

7. The device of claim 1 further comprising a counter back-electrode that is an electrically conductive material.

8. The device of claim 1 wherein said other layer is one or more absorber layers; and wherein said one or more absorber layers are organic or inorganic.

9. The device of claim 8 wherein said one or more absorber layers are formed of at least one of CdTe, CIGS, nc-Si, dyes, and quantum dots.

10. The device of claim 1 wherein said active material alone or in combination with other materials form a void in said cavity into which materials are disposed to form a nano-element within the dome-array feature.

11. The device of claim 10 wherein said nano-element contributes to one or both of light collection and trapping and photogenerated entity collection.

12. The device of claim 1 wherein the dome-like array architecture device is a photovoltaic cell.

13. A process for forming a dome-like array structure comprising:
disposing an active layer into a series of empty periodically positioned cavities of a dome-like array template working mold material each of said series of empty periodically positioned cavities having curvature variations of the interior surface of said dome-like array cavities optimized for device efficiency, reduction of performance sensitivity to light impingement angle, or a combination thereof;
disposing in said series of cavities at least one of contact layers, spacer/transport layers, and electrode layers.

14. The process of claim 13 wherein said mold material is transparent and integral to the device and positioned as a light contacting side.

15. The processes of claim 13 wherein the active material alone or in combination with one or more of contact layers, spacer/transport layers, and electrode layers disposed in said series of empty periodically positioned cavities of said dome-array template working mold material form a void into which materials are disposed to form a nano-element.

16. The process of claim 13 wherein said mold material is comprised of one of a glass-like material, a polymer, or a transparent conductive oxide.

17. The process of claim 14 wherein said mold material is supported by glass or transparent plastic or glass foil rendering the configuration a superstrate solar cell.

18. The process of claim 13 wherein said mold material is electrically conductive.
